(19) United States
(12) Patent Application Publication
(10) Pub. No.: US 2018/0213677 A1
(43) Pub. Date: Jul. 26, 2018

(54) LIQUID-COOLING HEAT DISSIPATION DEVICE

(71) Applicant: AURAS Technology Co., Ltd., New Taipei City (TW)

(72) Inventors: AN-CHIH WU, New Taipei City (TW); MU-SHU FAN, New Taipei City (TW); CHIEN-YU CHEN, New Taipei City (TW)

(21) Appl. No.: 15/437,999

(22) Filed: Feb. 21, 2017

(30) Foreign Application Priority Data
Jan. 25, 2017 (TW) 106102953

(51) Int. Cl. H05K 7/20

(52) U.S. Cl. CPC H05K 7/20254; H01L 23/473; H05K 7/20281

(57) ABSTRACT

A liquid-cooling heat dissipation device includes a thermally conductive base and a covering structure. The thermally conductive base has a bottom surface and a top surface opposed to the bottom surface. The bottom surface is in contact with a heat source. A heat dissipation structure is formed on the top surface. The thermally conductive base is covered by the covering structure. An input chamber and an output chamber are defined by the thermally conductive base and the covering structure collaboratively. The input chamber is disposed over the heat dissipation structure and has an entrance. The output chamber has an exit. The input chamber is a tapered space. A vertical height of the input chamber is gradually decreased in a direction from the entrance toward the exit. Consequently, liquid flowing into the input chamber through the entrance is guided to the heat dissipation structure.

### FIELD OF THE INVENTION

The present invention relates to a heat dissipation device, and more particularly to a liquid-cooling heat dissipation device.

### BACKGROUND OF THE INVENTION

FIG. 1A is a schematic perspective view illustrating a conventional liquid-cooling heat dissipation device. FIG. 1B is a schematic cross-sectional view of the liquid-cooling heat dissipation device as shown in FIG. 1A and taken along the line 1B-1B. The liquid-cooling heat dissipation device 1 is a cold plate. As shown in FIGS. 1A and 1B, the liquid-cooling heat dissipation device 1 comprises a thermally conductive base 2 and a covering structure 3. The thermally conductive base 2 has a bottom surface 21 and a top surface 22, which are opposed to each other. The bottom surface 21 is contacted with a heat source 8. Consequently, the heat is absorbed by the bottom surface 21 and transferred to the top surface 22. Moreover, a heat dissipation structure 23 is formed on the top surface 22 of the thermally conductive base 2 in order to increase the contact area between the thermally conductive base 2 and the liquid. Moreover, the thermally conductive base 2 is covered by the covering structure 3. Consequently, an active chamber 4 is defined by the thermally conductive base 2 and the covering structure 3 collaboratively. However, the conventional liquid-cooling heat dissipation device still has some drawbacks. For example, the liquid-cooling heat dissipation device is not equipped with any flow-guiding structure within the active chamber 4. After the liquid flows into the active chamber 4, only a portion of the liquid flows through the heat dissipation structure 23 to remove heat from the heat dissipation structure 23. Under this circumstance, the heat dissipating efficiency is usually unsatisfied.

### SUMMARY OF THE INVENTION

For solving the drawbacks of the conventional technology, the present invention provides an improved liquid-cooling heat dissipation device. The liquid-cooling heat dissipation device includes a thermally conductive base and a covering structure. An input chamber and an output chamber are defined by the thermally conductive base and the covering structure collaboratively. The vertical height of the input chamber is gradually decreased in the direction from an entrance toward an exit. Since the liquid entering the input chamber is guided to the heat dissipation structure, the contact area between the liquid and the heat dissipation structure is increased. Moreover, the liquid-cooling heat dissipation device further comprises a guiding plate between the thermally conductive base and the covering structure collaboratively. Due to the guiding plate, the liquid is precisely guided to strike the heat dissipation structure. Consequently, the cooling efficacy is enhanced.

In accordance with an aspect of the present invention, there is provided a liquid-cooling heat dissipation device. The liquid-cooling heat dissipation device includes a thermally conductive base and a covering structure. The thermally conductive base has a bottom surface and a top surface. The bottom surface and the top surface are opposed to each other. The bottom surface is in contact with a heat source. A heat dissipation structure is formed on the top surface. The thermally conductive base is covered by the covering structure. An input chamber and an output chamber are defined by the thermally conductive base and the covering structure collaboratively. The input chamber is disposed over the heat dissipation structure and has an entrance. The output chamber has an exit. The input chamber is a tapered space. A vertical height of the input chamber is gradually decreased in a direction from the entrance toward the exit. Consequently, liquid flowing into the input chamber through the entrance is guided to the heat dissipation structure.

In an embodiment, the heat dissipation structure is a plate fin heat sink, a pin fin heat sink, a groove type heat sink, a rough surface heat sink or any other appropriate heat sink.

In an embodiment, a circulative runner is formed in the top surface of the thermally conductive base and arranged around the heat dissipation structure, the liquid-cooling heat dissipation device further includes a guiding plate between the thermally conductive base and the covering structure, and the guiding plate includes an inlet and an outlet. After the liquid flows into the input chamber, the liquid flows to the heat dissipation structure through the inlet. After the liquid passes through the heat dissipation structure, the liquid flows through the circulative runner and flows into the output chamber through the outlet.

In an embodiment, the guiding plate is attached on a bottom side of the input chamber. After the liquid flows into the input chamber through the entrance, the liquid is only allowed to flow to the heat dissipation structure through the inlet.

In an embodiment, the inlet is disposed under the input chamber, and the outlet is disposed under the output chamber.

In an embodiment, an area of the inlet is smaller than an area of the outlet.

In an embodiment, a width of the inlet is gradually decreased in a direction from the input chamber toward the output chamber.

In an embodiment, a width of the inlet is gradually decreased in the direction from the output chamber toward the input chamber.

In an embodiment, the inlet includes a first part and a second part, and the second part is wider than the first part.

In an embodiment, the second part has a circular shape, an elliptic shape, a rectangular shape, a trapezoid shape or a rhombus shape.

In an embodiment, the heat dissipation structure includes plural parallel fins in a first direction, and the inlet is arranged in a direction perpendicular to the first direction, so that the liquid is allowed to flow into a seam between every two adjacent fins of the plural fins.

In an embodiment, a circulative runner is formed in the top surface of the thermally conductive base and arranged around the heat dissipation structure, the liquid-cooling heat dissipation device further includes a guiding plate between the thermally conductive base and the covering structure, and the guiding plate includes an inlet. After the liquid flows into the input chamber, the liquid flows to the heat dissipation structure through the inlet. After the liquid passes through the heat dissipation structure, the liquid flows through the circulative runner and flows into the output chamber.

In an embodiment, the guiding plate is attached on a bottom side of the input chamber. After the liquid flows into the input chamber through the entrance, the liquid is only allowed to flow to the heat dissipation structure through the inlet.

In an embodiment, an area of the inlet is smaller than an area of the outlet.

In an embodiment, a width of the inlet is gradually decreased in a direction from the input chamber toward the output chamber.

In an embodiment, a width of the inlet is gradually decreased in the direction from the output chamber toward the input chamber.

In an embodiment, the inlet includes a first part and a second part, and the second part is wider than the first part.

In an embodiment, the second part has a circular shape, an elliptic shape, a rectangular shape, a trapezoid shape or a rhombus shape.

In an embodiment, the heat dissipation structure includes plural parallel fins in a first direction, and the inlet is arranged in a direction perpendicular to the first direction, so that the liquid is allowed to flow into a seam between every two adjacent fins of the plural fins.

In accordance with an aspect of the present invention, there is provided a liquid-cooling heat dissipation device. The liquid-cooling heat dissipation device includes a thermally conductive base, a covering structure and a guiding plate. The thermally conductive base has a bottom surface and a top surface. The bottom surface and the top surface are opposed to each other. The bottom surface is in contact with a heat source. A heat dissipation structure is formed on the top surface. The thermally conductive base is covered by the covering structure. An input chamber and an output chamber are defined by the thermally conductive base and the covering structure collaboratively. The input chamber is disposed over the heat dissipation structure and has an entrance. The output chamber has an exit. The guiding plate is clamped between the thermally conductive base and the covering structure, and includes an edge, an inlet and an outlet. After liquid flows into the input chamber, the liquid flows to the heat dissipation structure through the inlet. After the liquid passes through the heat dissipation structure, the liquid flows into the output chamber through the outlet.

In an embodiment, a bent structure is protruded downwardly from a periphery of the covering structure, and the edge of the guiding plate and the top surface of the thermally conductive base are covered by the bent structure.

In an embodiment, a vertical height of the inlet is larger than a vertical height of the edge of the guiding plate, so that the heat dissipation structure and the guiding plate are partially overlapped with each other in a vertical direction.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating a conventional liquid-cooling heat dissipation device;

FIG. 1B is a schematic cross-sectional view of the liquid-cooling heat dissipation device as shown in FIG. 1A and taken along the line 1B-1B;

FIG. 2A is a schematic perspective view illustrating a liquid-cooling heat dissipation device according to a first embodiment of the present invention;

FIG. 2B is a schematic exploded view illustrating the liquid-cooling heat dissipation device according to the first embodiment of the present invention;

FIG. 2C is a schematic cross-sectional view of the liquid-cooling heat dissipation device as shown in FIG. 2A and taken along the line 2C-2C;

FIG. 3A is a schematic perspective view illustrating a liquid-cooling heat dissipation device according to a second embodiment of the present invention;

FIG. 3B is a schematic exploded view illustrating the liquid-cooling heat dissipation device according to the second embodiment of the present invention;

FIG. 3C is a schematic cross-sectional view of the liquid-cooling heat dissipation device as shown in FIG. 3A and taken along the line 3C-3C;

FIG. 4 is a schematic exploded view illustrating a variant example of the liquid-cooling heat dissipation device according to the second embodiment of the present invention;

FIG. 5 is a schematic exploded view illustrating another variant example of the liquid-cooling heat dissipation device according to the second embodiment of the present invention;

FIG. 6A is a schematic perspective view illustrating a liquid-cooling heat dissipation device according to a third embodiment of the present invention;

FIG. 6B is a schematic exploded view illustrating the liquid-cooling heat dissipation device according to the third embodiment of the present invention; and

FIG. 6C is a schematic cross-sectional view of the liquid-cooling heat dissipation device as shown in FIG. 6A and taken along the line 6C-6C.

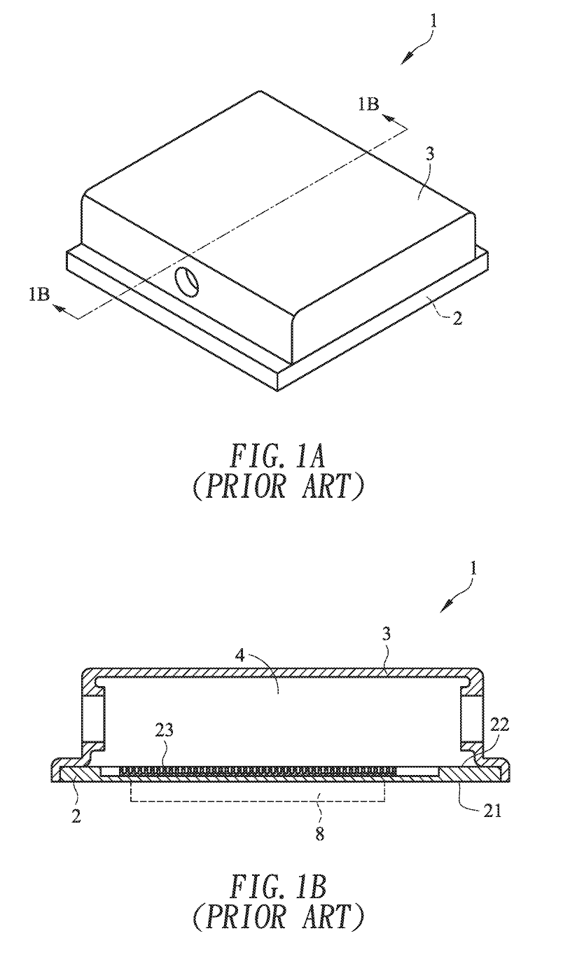

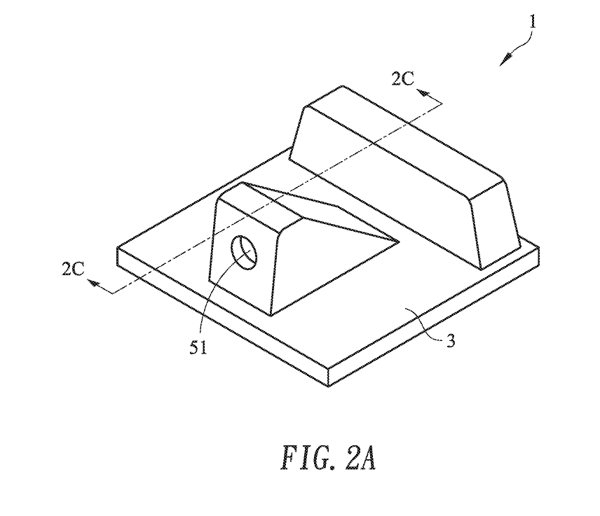

### DETAILED DESCRIPTION OF THE PREFERRED EMBODIMENT

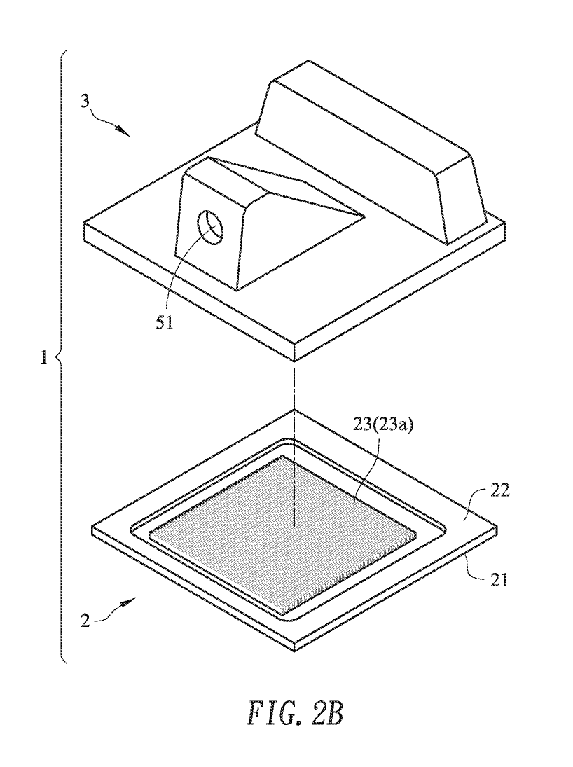

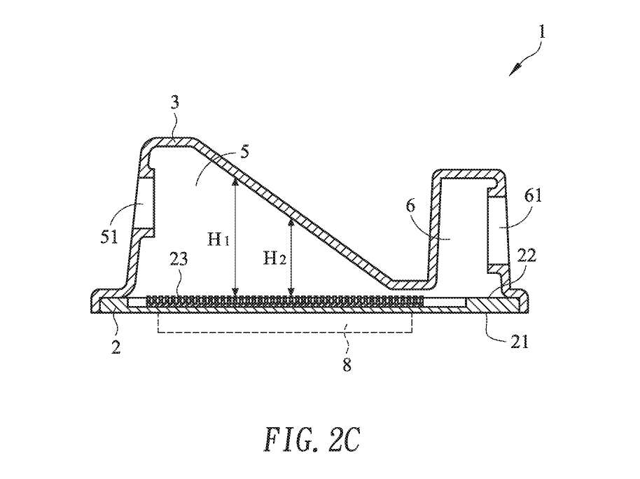

FIG. 2A is a schematic perspective view illustrating a liquid-cooling heat dissipation device according to a first embodiment of the present invention. FIG. 2B is a schematic exploded view illustrating the liquid-cooling heat dissipation device according to the first embodiment of the present invention. FIG. 2C is a schematic cross-sectional view of the liquid-cooling heat dissipation device as shown in FIG. 2A and taken along the line 2C-2C. In the first embodiment of the present invention, the liquid-cooling heat dissipation device 1 comprises a thermally conductive base 2 and a covering structure 3. The thermally conductive base 2 has a bottom surface 21 and a top surface 22, which are opposed to each other. The bottom surface 21 is contacted with a heat source 8. Consequently, the heat is absorbed by the bottom surface 21 and transferred to the top surface 22. Moreover, a heat dissipation structure 23 is formed on the top surface 22 of the thermally conductive base 2 in order to increase the contact area between the thermally conductive base 2 and the liquid and increase the heat dissipating efficiency. Moreover, the thermally conductive base 2 is covered by the covering structure 3. Consequently, an input chamber 5 and an output chamber 6 are defined by the thermally conductive base 2 and the covering structure 3 collaboratively. The input chamber 5 has an entrance 51. The output chamber 6 has an exit 61.

For allowing the liquid in the input chamber 5 to flow to the heat dissipation structure 23, the input chamber 5 is specially designed to have a tapered space. For example, the vertical height of the input chamber 5 is gradually decreased in the direction from the entrance 51 toward the exit 61. As shown in FIG. 2C, the vertical height H2 of the input chamber 5 close to the exit 61 is smaller than the vertical height H1 of the input chamber 5 close to the entrance 51. After the liquid is introduced into the input chamber 5 through the entrance 51, the liquid is guided downwardly to the heat dissipation structure 23 by the tapered space of the input chamber 5. Since the possibility of contacting the liquid with the heat dissipation structure 23 is increased, the heat can be dissipated away more efficiently.

In this embodiment, the heat dissipation structure 23 is a plate fin heat sink. As shown in FIG. 2B, the heat dissipation structure 23 comprises plural parallel plate fins 23a. For example, in another embodiment, the heat dissipation structure 23 is a pin fin heat sink, a groove type heat sink, a rough surface heat sink or any other appropriate heat sink. The profile of the heat dissipation structure 23 is not restricted as long as the contact area between the liquid and the heat dissipation structure 23 is increased.

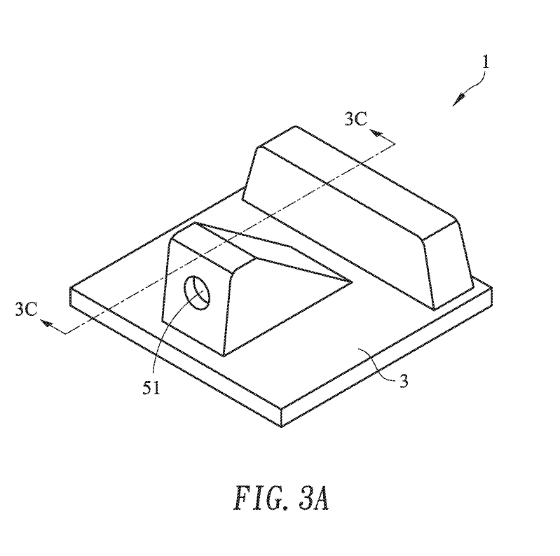

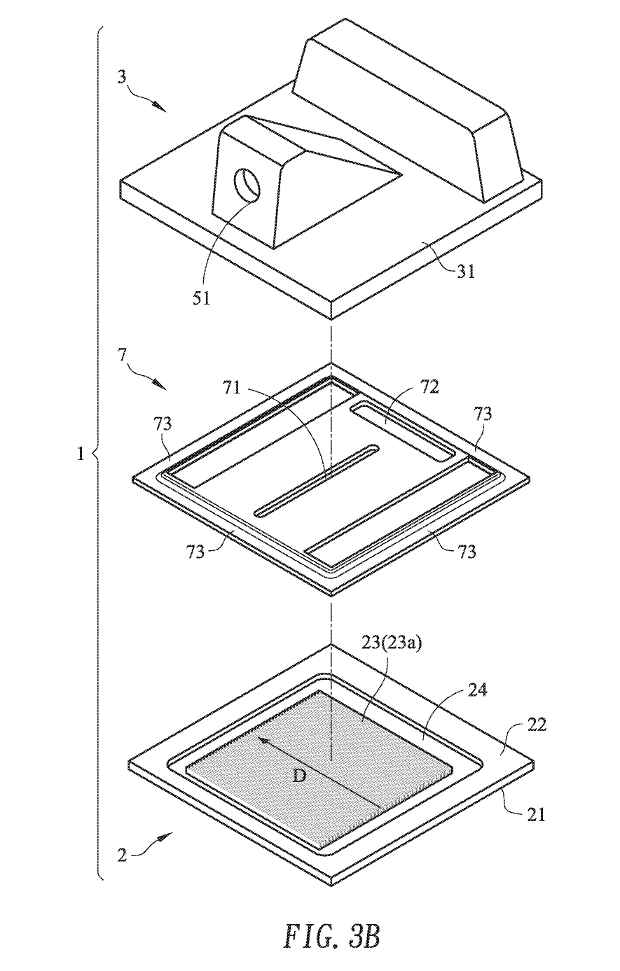

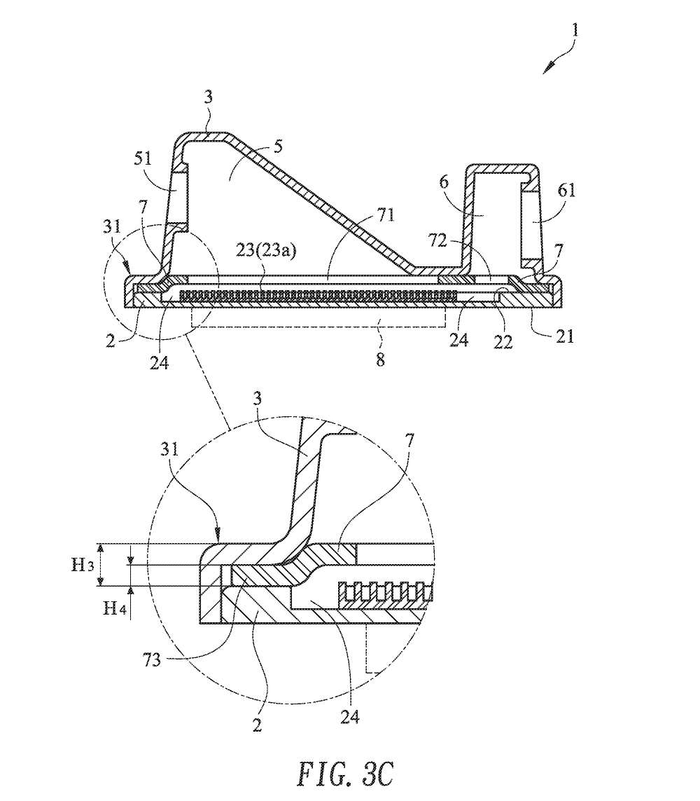

FIG. 3A is a schematic perspective view illustrating a liquid-cooling heat dissipation device according to a second embodiment of the present invention. FIG. 3B is a schematic exploded view illustrating the liquid-cooling heat dissipation device according to the second embodiment of the present invention. FIG. 3C is a schematic cross-sectional view of the liquid-cooling heat dissipation device as shown in FIG. 3A and taken along the line 3C-3C. In the second embodiment of the present invention, the liquid-cooling heat dissipation device 1 comprises a thermally conductive base 2, a covering structure 3 and a guiding plate 7. The thermally conductive base 2 has a bottom surface 21 and a top surface 22, which are opposed to each other. The bottom surface 21 is contacted with a heat source 8. Consequently, the heat is absorbed by the bottom surface 21 and transferred to the top surface 22. A heat dissipation structure 23 is formed on the top surface 22 of the thermally conductive base 2 in order to increase the contact area between the thermally conductive base 2 and the liquid and increase the heat dissipating efficiency. Moreover, a circulative runner 24 is formed in the top surface 22 of the thermally conductive base 2 and arranged around the heat dissipation structure 23. After the liquid passes through the heat dissipation structure 23, the liquid is collected in the circulative runner 24. Moreover, the thermally conductive base 2 is covered by the covering structure 3. Consequently, an input chamber 5 and an output chamber 6 are defined by the thermally conductive base 2 and the covering structure 3 collaboratively. The input chamber 5 has an entrance 51. The output chamber 6 has an exit 61.

Like the first embodiment, the input chamber 5 has a tapered space for guiding the liquid toward the heat dissipation structure 23. Especially, the guiding plate 7 is arranged between the thermally conductive base 2 and the covering structure 3. By the guiding plate 7, the liquid in the input chamber 5 is guided to the heat dissipation structure 23 more intensively. Especially, the liquid is guided to a middle region of the heat dissipation structure 23 or any other region of the heat dissipation structure 23 that requires the liquid to flow through. In this embodiment, the guiding plate 7 comprises an inlet 71 and an outlet 72. The inlet 71 is disposed under the input chamber 5. The outlet 72 is disposed under the output chamber 6. After the liquid flows into the input chamber 5, the liquid flows to the heat dissipation structure 23 through the inlet 71. After the liquid passes through the heat dissipation structure 23, the liquid is introduced into the circulative runner 24 and collected by the circulative runner 24. Then, the liquid flows into the output chamber 6 through the outlet 72.

For allowing the liquid to pressurize the heat dissipation structure 23, the guiding plate 7 is attached on a bottom side of the input chamber 5 by a secure coupling means. Consequently, after the liquid flows into the input chamber 5 through the entrance 51, a greater portion of the liquid is only able to flow to the heat dissipation structure 23 through the inlet 71. The guiding plate 7 may be specially designed. In an embodiment, the area of the inlet 71 is smaller than the area of the outlet 72. Consequently, after the liquid pressurizes and strikes the heat dissipation structure 23, the liquid flows to the output chamber 6 smoothly.

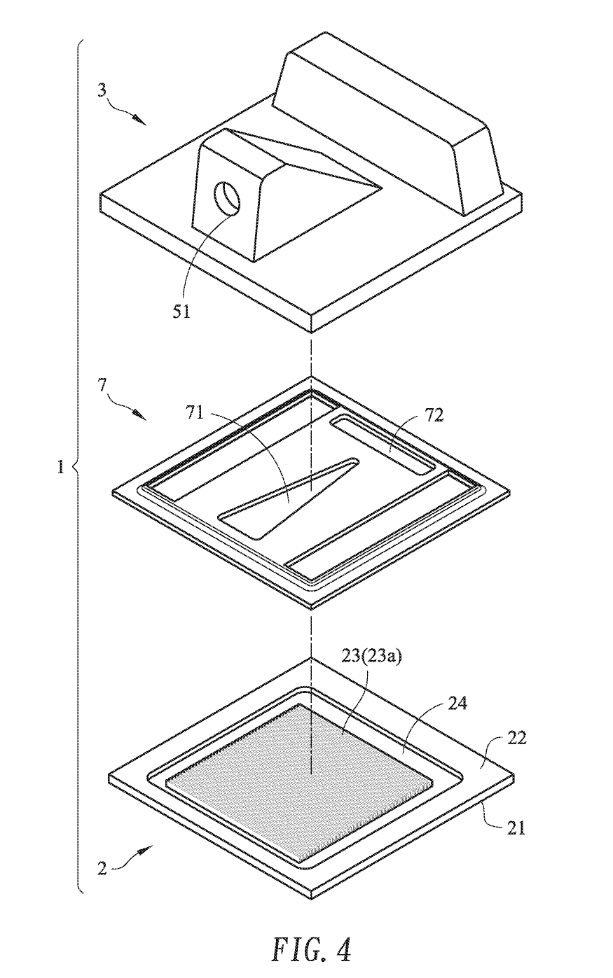

Moreover, the profile of the guiding plate 7 may be varied and designed according to the practical requirements. FIG. 4 is a schematic exploded view illustrating a variant example of the liquid-cooling heat dissipation device according to the second embodiment of the present invention. In this embodiment, the profile of the inlet of the guiding plate is modified. In case that the heat source 8 under the thermally conductive base 2 has a high temperature region close to the location corresponding to entrance 51 according to experiments or calculations, the width of the inlet 71 is gradually decreased in the direction from the input chamber 5 toward the output chamber 6. Consequently, the liquid is guided to strike the high temperature region of the heat dissipation structure 23. Similarly, in case that the high temperature region of the heat source 8 is close to the location corresponding to exit 61, the width of the inlet 71 is gradually decreased in the direction from the output chamber 6 toward the input chamber 5.

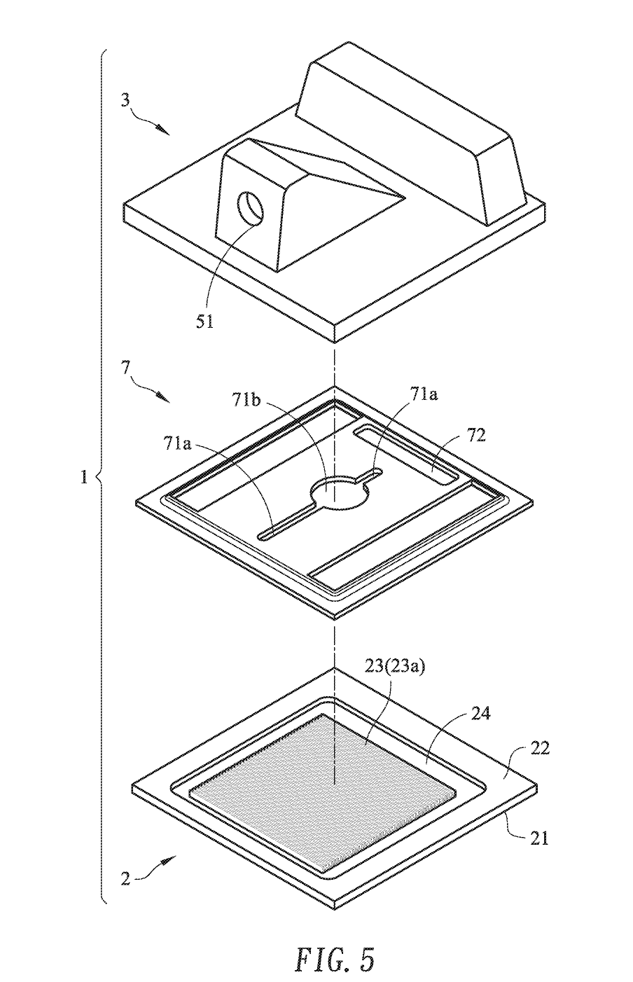

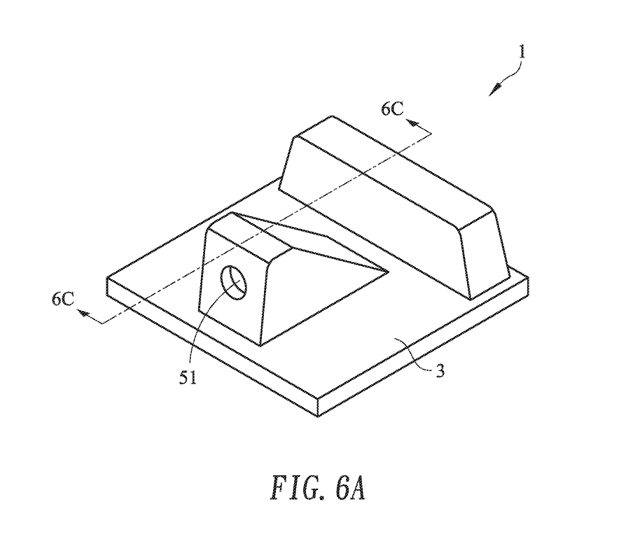

In the above embodiment, the width of the inlet 71 is gradually decreased. For example, in case that the heat source 8 has a high temperature region, the portion of the inlet 71 corresponding to the high temperature region of the heat source 8 is widened. FIG. 5 is a schematic exploded view illustrating another variant example of the liquid-cooling heat dissipation device according to the second embodiment of the present invention. As shown in FIG. 5, the inlet 71 comprises a first part 71a and a second part 71b. The second part 71b is wider than the first part 71a. In this situation, the high temperature region of the heat source 8 is located under the second part 71a. It is noted that the shape of the second part 71b is not restricted. For example, the second part 71b has a circular shape, an elliptic shape, a rectangular shape, a trapezoid shape, a rhombus shape or any other appropriate shape.

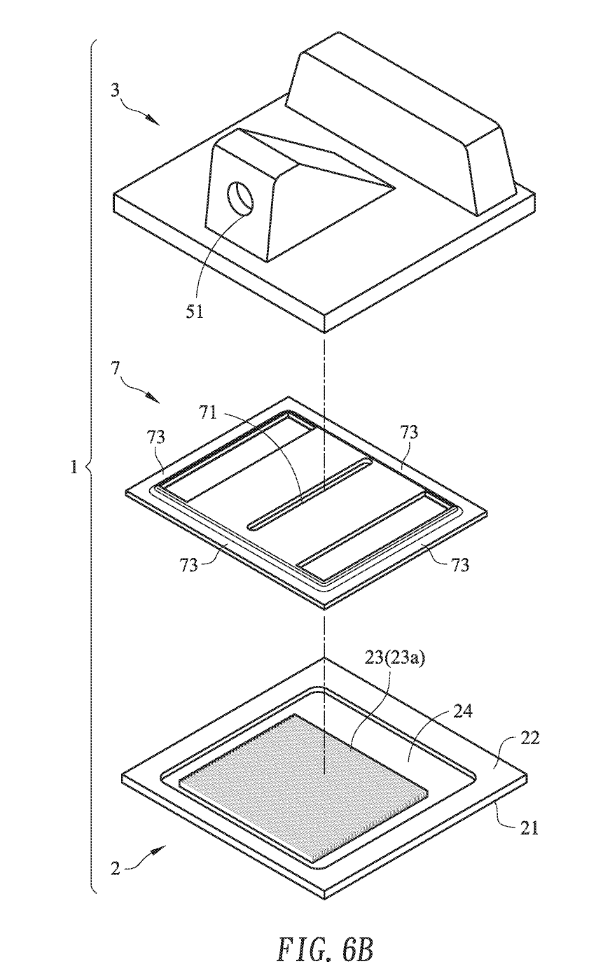

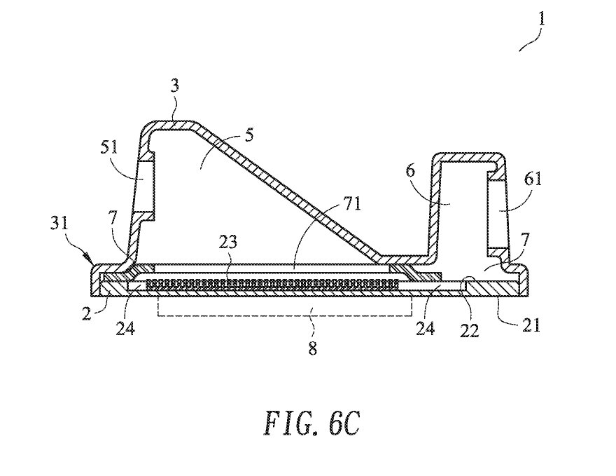

FIG. 6A is a schematic perspective view illustrating a liquid-cooling heat dissipation device according to a third embodiment of the present invention. FIG. 6B is a schematic exploded view illustrating the liquid-cooling heat dissipation device according to the third embodiment of the present invention. FIG. 6C is a schematic cross-sectional view of the liquid-cooling heat dissipation device as shown in FIG. 6A and taken along the line 6C-6C. In the third embodiment of the present invention, the liquid-cooling heat dissipation device 1 comprises a thermally conductive base 2, a covering structure 3 and a guiding plate 7. The thermally conductive base 2 has a bottom surface 21 and a top surface 22, which are opposed to each other. The bottom surface 21 is contacted with a heat source 8. Consequently, the heat is absorbed by the bottom surface 21 and transferred to the top surface 22. A heat dissipation structure 23 is formed on the top surface 22 of the thermally conductive base 2 in order to increase the contact area between the thermally conductive base 2 and the liquid and increase the heat dissipating efficiency. Moreover, a circulative runner 24 is formed in the top surface 22 of the thermally conductive base 2 and arranged around the heat dissipation structure 23. After the liquid passes through the heat dissipation structure 23, the liquid is collected in the circulative runner 24. Moreover, the thermally conductive base 2 is covered by the covering structure 3. Consequently, an input chamber 5 and an output chamber 6 are defined by the thermally conductive base 2 and the covering structure 3 collaboratively. The input chamber 5 has an entrance 51. The output chamber 6 has an exit 61.

Like the first embodiment, the input chamber 5 has a tapered space for guiding the liquid toward the heat dissipation structure 23. Especially, the guiding plate 7 is arranged between the thermally conductive base 2 and the covering structure 3. By the guiding plate 7, the liquid in the input chamber 5 is guided to the heat dissipation structure 23 more intensively. Especially, the liquid is guided to a middle region of the heat dissipation structure 23 or any other region of the heat dissipation structure 23 that requires the liquid to flow through. In comparison with the second embodiment, the guiding plate 7 of this embodiment is not equipped with the outlet. For example, the region originally containing the outlet is cut off. Consequently, the guiding plate 7 only comprises the inlet 71. The inlet 71 is still disposed under the input chamber 5. After the liquid flows into the input chamber 5, the liquid flows to the heat dissipation structure 23 through the inlet 71. After the liquid passes through the heat dissipation structure 23, the liquid is introduced into the circulative runner 24 and collected by the circulative runner 24. Then, the liquid flows into the output chamber 6 through the outlet 72.

In this embodiment, the heat dissipation structure 23 is a plate fin heat sink. In another embodiment, the heat dissipation structure 23 is a pin fin heat sink, a groove type heat sink, a rough surface heat sink or any other appropriate heat sink. The profile of the heat dissipation structure 23 is not restricted as long as the contact area between the liquid and the heat dissipation structure 23 is increased. As shown in FIG. 6B, the heat dissipation structure 23 comprises plural parallel plate fins 23a, which are arranged in a first direction D. In this embodiment, the inlet 71 is arranged in a direction perpendicular to the first direction D. After the liquid flows through the inlet 71, the liquid can still be introduced into the seams between the adjacent plate fins 23a of the heat dissipation structure 23. Consequently, the heat dissipating efficiency is enhanced.

Similarly, the inlet 71 of the guiding plate 7 is specially designed. The concepts of designing the inlet 71 of this embodiment are similar to those of the second embodiment. For allowing the liquid to pressurize the heat dissipation structure 23, the guiding plate 7 is attached on a bottom side of the input chamber 5 by a secure coupling means. Consequently, after the liquid flows into the input chamber 5 through the entrance 51, a greater portion of the liquid is only able to flow to the heat dissipation structure 23 through the inlet 71. The variant examples of the inlet 71 are similar to those of the second embodiment. For example, the width of the inlet 71 is gradually decreased in the direction from the input chamber 5 toward the output chamber 6, or the width of the inlet 71 is gradually decreased in the direction from the output chamber 6 toward the input chamber 5. Alternatively, the inlet 71 comprises a first part 71a and a second part 71b. The second part 71b is wider than the first part 71a. In this situation, the high temperature region of the heat source 8 is located under the second part 71a. It is noted that the shape of the second part 71b is not restricted. For example, the second part 71b has a circular shape, an elliptic shape, a rectangular shape, a trapezoid shape, a rhombus shape or any other appropriate shape.

In the above embodiments, the thermally conductive base 2, the covering structure 3 and the guiding plate 7 are made of metallic material. For example, the metallic material is metal or alloy containing copper, aluminum or stainless steel. Due to the material of the covering structure 3, the heat dissipating efficacy is enhanced and the thermally conductive base 2, the covering structure 3 and the guiding plate 7 are combined together more securely. Generally, the thermally conductive base 2, the covering structure 3 and the guiding plate 7 are combined together by a metal machining means such as a braze-welding means or a soft soldering means. It is noted that the way of combining these component is not restricted.

For securely placing the guiding plate 7 between the thermally conductive base 2 and the covering structure 3, the covering structure 3 is further modified. As shown in FIG. 3C, a stepped bent structure 31 is protruded downwardly from the periphery of the covering structure 3. By the stepped bent structure 31, the guiding plate 7 is clamped between the thermally conductive base 2 and the covering structure 3. After four edges 73 of the guiding plate 7 and the top surface 22 of the thermally conductive base 2 are covered by the stepped bent structure 31, the thermally conductive base 2, the covering structure 3 and the guiding plate 7 are well machined and combined together. In the third embodiment, only three edges 73 of the guiding plate 7 are contacted with the covering structure 3. However, the edges 73 of the guiding plate 7 are still covered by the stepped bent structure 31 and securely clamped between the thermally conductive base 2 and the covering structure 3.

For reducing the overall height of the liquid-cooling heat dissipation device 1, as shown in FIGS. 3C and 6C, the vertical height H3 of the inlet 71 is larger than the vertical height H4 of the edge 73 of the guiding plate 7. Since the guiding plate 7 and the heat dissipation structure 23 are partially overlapped with each other in the vertical direction, the overall thickness of the liquid-cooling heat dissipation device 1 is reduced.

What is claimed is:

1. A liquid-cooling heat dissipation device, comprising:
a thermally conductive base having a bottom surface and a top surface, wherein the bottom surface and the top surface are opposed to each other, the bottom surface is in contact with a heat source, and a heat dissipation structure is formed on the top surface; and
a covering structure, wherein the thermally conductive base is covered by the covering structure, and an input chamber and an output chamber are defined by the thermally conductive base and the covering structure collaboratively, wherein the input chamber is disposed over the heat dissipation structure and has an entrance, and the output chamber has an exit,
wherein the input chamber is a tapered space, and a vertical height of the input chamber is gradually decreased in a direction from the entrance toward the exit, so that liquid flowing into the input chamber through the entrance is guided to the heat dissipation structure.

2. The liquid-cooling heat dissipation device according to claim 1, wherein the heat dissipation structure is a plate fin heat sink, a pin fin heat sink, a groove type heat sink, a rough surface heat sink or any other appropriate heat sink.

3. The liquid-cooling heat dissipation device according to claim 1, wherein a circulative runner is formed in the top surface of the thermally conductive base and arranged around the heat dissipation structure, the liquid-cooling heat dissipation device further comprises a guiding plate between the thermally conductive base and the covering structure, and the guiding plate comprises an inlet and an outlet, wherein after the liquid flows into the input chamber, the liquid flows to the heat dissipation structure through the inlet, wherein after the liquid passes through the heat dissipation structure, the liquid flows through the circulative runner and flows into the output chamber through the outlet.

4. The liquid-cooling heat dissipation device according to claim 3, wherein the guiding plate is attached on a bottom side of the input chamber, wherein after the liquid flows into the input chamber through the entrance, the liquid is only allowed to flow to the heat dissipation structure through the inlet.

5. The liquid-cooling heat dissipation device according to claim 3, wherein the inlet is disposed under the input chamber, and the outlet is disposed under the output chamber.

6. The liquid-cooling heat dissipation device according to claim 3, wherein an area of the inlet is smaller than an area of the outlet.

7. The liquid-cooling heat dissipation device according to claim 3, wherein a width of the inlet is gradually decreased in a direction from the input chamber toward the output chamber.

8. The liquid-cooling heat dissipation device according to claim 3, wherein a width of the inlet is gradually decreased in the direction from the output chamber toward the input chamber.

9. The liquid-cooling heat dissipation device according to claim 3, wherein the inlet comprises a first part and a second part, and the second part is wider than the first part.

10. The liquid-cooling heat dissipation device according to claim 9, wherein the second part has a circular shape, an elliptic shape, a rectangular shape, a trapezoid shape or a rhombus shape.

11. The liquid-cooling heat dissipation device according to claim 3, wherein the heat dissipation structure comprises plural parallel fins in a first direction, and the inlet is arranged in a direction perpendicular to the first direction, so that the liquid is allowed to flow into a seam between every two adjacent fins of the plural fins.

12. The liquid-cooling heat dissipation device according to claim 1, wherein a circulative runner is formed in the top surface of the thermally conductive base and arranged around the heat dissipation structure, the liquid-cooling heat dissipation device further comprises a guiding plate between the thermally conductive base and the covering structure, and the guiding plate comprises an inlet, wherein after the liquid flows into the input chamber, the liquid flows to the heat dissipation structure through the inlet, wherein after the liquid passes through the heat dissipation structure, the liquid flows through the circulative runner and flows into the output chamber.

13. The liquid-cooling heat dissipation device according to claim 12, wherein the guiding plate is attached on a bottom side of the input chamber, wherein after the liquid flows into the input chamber through the entrance, the liquid is only allowed to flow to the heat dissipation structure through the inlet.

14. The liquid-cooling heat dissipation device according to claim 12, wherein an area of the inlet is smaller than an area of the outlet.

15. The liquid-cooling heat dissipation device according to claim 12, wherein a width of the inlet is gradually decreased in a direction from the input chamber toward the output chamber.

16. The liquid-cooling heat dissipation device according to claim 12, wherein a width of the inlet is gradually decreased in the direction from the output chamber toward the input chamber.

17. The liquid-cooling heat dissipation device according to claim 12, wherein the inlet comprises a first part and a second part, and the second part is wider than the first part.

18. The liquid-cooling heat dissipation device according to claim 12, wherein the second part has a circular shape, an elliptic shape, a rectangular shape, a trapezoid shape or a rhombus shape.

19. The liquid-cooling heat dissipation device according to claim 13, wherein the heat dissipation structure comprises plural parallel fins in a first direction, and the inlet is arranged in a direction perpendicular to the first direction, so that the liquid is allowed to flow into a seam between every two adjacent fins of the plural fins.

20. A liquid-cooling heat dissipation device, comprising:
a thermally conductive base having a bottom surface and a top surface, wherein the bottom surface and the top surface are opposed to each other, the bottom surface is in contact with a heat source, and a heat dissipation structure is formed on the top surface;
a covering structure, wherein the thermally conductive base is covered by the covering structure, and an input chamber and an output chamber are defined by the thermally conductive base and the covering structure collaboratively, wherein the input chamber is disposed over the heat dissipation structure and has an entrance, and the output chamber has an exit; and
a guiding plate clamped between the thermally conductive base and the covering structure, and comprising an edge, an inlet and an outlet, wherein after liquid flows into the input chamber, the liquid flows to the heat dissipation structure through the inlet, wherein after the liquid passes through the heat dissipation structure, the liquid flows into the output chamber through the outlet.

21. The liquid-cooling heat dissipation device according to claim 20, wherein a bent structure is protruded downwardly from a periphery of the covering structure, and the edge of the guiding plate and the top surface of the thermally conductive base are covered by the bent structure.

22. The liquid-cooling heat dissipation device according to claim 20, wherein a vertical height of the inlet is larger than a vertical height of the edge of the guiding plate, so that the heat dissipation structure and the guiding plate are partially overlapped with each other in a vertical direction.
